(19) United States
(12) Patent Application Publication
(10) Pub. No.: US 2026/0179704 A1
(43) Pub. Date: Jun. 25, 2026

(54) MEMORY DEVICE AND MEMORY SYSTEM

(71) Applicant: SK hynix Inc., Icheon-si (KR)

(72) Inventors: Seung Min BAEK, San Jose, CA (US); Hoiju CHUNG, San Jose, CA (US); Eui Sang OH, San Jose, CA (US)

(21) Appl. No.: 19/219,649

(22) Filed: May 27, 2025

Related U.S. Application Data
(60) Provisional application No. 63/736,139, filed on Dec. 19, 2024.
(60) Provisional application No. 63/773,048, filed on Mar. 17, 2025.

(51) Int. Cl. G11C 29/02; G11C 16/04; G11C 16/08; G11C 16/26

(52) U.S. Cl. CPC G11C 29/022; G11C 16/0483; G11C 16/08; G11C 16/26

(57) ABSTRACT

A memory device includes a plurality of cell blocks arranged in an array in a row direction and a column direction, and divided into cell groups that share a plurality of sub-word lines in the row direction; and a control circuit configured to, during an access operation, activate a first sub-word line arranged in a first cell group and a second sub-word line arranged in a second cell group, among the cell groups, and control data to be input/output to/from odd-numbered cell blocks in the first cell group and even-numbered cell blocks in the second cell group, or to/from even-numbered cell blocks in the first cell group and odd-numbered cell blocks in the second cell group.

### CROSS-REFERENCE TO RELATED APPLICATIONS

The present application claims the benefit of priority under 35 U.S.C. § 119(e) to U.S. Provisional Patent Application No. 63/736,139 , filed on Dec. 19, 2024, and U.S. Provisional Patent Application No. 63/773,048, filed on Mar. 17, 2025, which are incorporated herein by reference in their entirety.

### BACKGROUND

### 1. Field

Various embodiments of the present disclosure relate to a semiconductor design technology, and more particularly, to a memory system including a memory device capable of responding to a fault in a sub-word line driver.

### 2. Description of the Related Art

In the early days of the semiconductor memory industry, when a memory chip passed a semiconductor fabrication process on the wafer, there were many original good dies with no defective memory cells. However, as the capacity of memory devices gradually increased, it becomes difficult to make a memory device completely free of defective memory cells, and at present, it may be said that there is likely no possibility that a memory device with no defective memory cells can be fabricated. As one solution to overcome this situation, a method of repairing defective memory cells of a memory device with redundant memory cells or a method of correcting an error in data of memory cells using an error correction code (ECC) engine is being used.

Currently, various methods are being discussed to manage the maximum number of error bits that may occur in a memory device within the error correction capability of the ECC engine.

### SUMMARY

Embodiments of the present disclosure are directed to a memory device and a memory system capable of increasing a page size by activating two sub-word lines according to a row address, and reducing the number of data bits output by a shared sub-word line driver, to thereby expand the error coverage of an ECC engine from the sub-word line level to the sub-word line driver level.

In accordance with an embodiment of the present disclosure, a memory device includes a plurality of cell blocks arranged in an array in a row direction and a column direction, and divided into cell groups that share a plurality of sub-word lines in the row direction; and a control circuit configured to, during an access operation, activate a first sub-word line arranged in a first cell group and a second sub-word line arranged in a second cell group, among the cell groups, and control data to be input/output to/from odd-numbered cell blocks in the first cell group and even-numbered cell blocks in the second cell group, or to/from even-numbered cell blocks in the first cell group and odd-numbered cell blocks in the second cell group.

In accordance with an embodiment of the present disclosure, a memory device includes a plurality of cell blocks arranged in an array in a row direction and a column direction, alternately sharing sub-word line drivers with adjacent cell blocks in the row direction; a row control circuit configured to activate first sub-word line drivers corresponding to a row address, and activate second sub-word line drivers corresponding to a paired row address according to a mode selection signal, during an access operation; and a path control circuit configured to control data to be input/output from odd-numbered cell blocks among cell blocks sharing the activated first sub-word line drivers, and even-numbered cell blocks among cell blocks sharing the activated second sub-word line drivers, according to the mode selection signal.

In accordance with an embodiment of the present disclosure, a memory device includes a plurality of banks each including a plurality of cell blocks arranged in an array in a row direction and a column direction and alternately sharing sub-word line drivers with adjacent cell blocks in the row direction, and configured to activate first sub-word line drivers corresponding to a row address and activate second sub-word line drivers corresponding to a paired row address according to a mode selection signal, during an access operation; and a path control circuit configured to control data to be input/output from odd-numbered cell blocks among cell blocks sharing the activated first sub-word line drivers and even-numbered cell blocks among cell blocks sharing the activated second sub-word line drivers, according to the mode selection signal.

In accordance with an embodiment of the present disclosure, a memory system includes at least one memory device; and a memory controller configured to provide a command and an address to the memory device and to transmit and receive data to and from the memory device, wherein the memory device includes: a plurality of cell blocks arranged in an array in a row direction and a column direction and divided into cell groups that share a plurality of sub-word lines in the row direction; and a control circuit configured to, during an access operation, activate a first sub-word line arranged in a first cell group and a second sub-word line arranged in a second cell group, and control the data to be input/output from odd-numbered cell blocks in the first cell group and even-numbered cell blocks in the second cell group, or from even-numbered cell blocks in the first cell group and odd-numbered cell blocks in the second cell group.

According to embodiments of the present disclosure, the memory device may prevent the occurrence of an uncorrectable error (UE) and maximize the error correction capability by limiting the maximum number of error bits that may be caused by a fault of a sub-word line driver, within the error correction capability of the ECC engine.

According to embodiments of the present disclosure, the memory device may provide optimized reliability, accessibility, and serviceability (RAS) operation by increasing the error relief capability of the memory controller. In addition, according to embodiments of the present disclosure, the memory device may provide optimized RAS operation while minimizing power consumption by selectively performing an operation under a normal condition or an operation under a double page condition, according to settings.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory device according to an embodiment of the present disclosure.

FIG. 2 is a diagram illustrating a memory cell array of FIG. 1 according to an embodiment of the present disclosure.

FIGS. 3A and 3B are diagrams for explaining a core region of FIG. 1.

FIG. 4 is a diagram illustrating local sense amplifiers allocated to one cell group according to an embodiment of the present disclosure.

FIGS. 5A and 5B are diagrams for explaining error coverage faults of a sub-word line driver.

FIG. 6 is a block diagram illustrating a sequence selection circuit of FIG. 1.

FIGS. 7A to 9B are diagrams for describing an operation of a sequence selection circuit of FIG. 6.

FIG. 10 is a block diagram illustrating a path setting circuit of FIG. 1.

FIGS. 11 to 13 are diagrams illustrating data input/output operations according to an embodiment of the present disclosure.

FIG. 14 is a block diagram of a memory device according to another embodiment of the present disclosure.

FIG. 15 is a detailed configuration diagram of a memory core of FIG. 14.

FIG. 16 is a block diagram illustrating a memory system including a memory module according to an embodiment of the present disclosure.

FIG. 17 is a block diagram illustrating a memory system including a stacked memory device according to an embodiment of the present disclosure.

FIG. 18 is a block diagram illustrating a mobile system including a memory device according to an embodiment of the present disclosure.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit or element intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

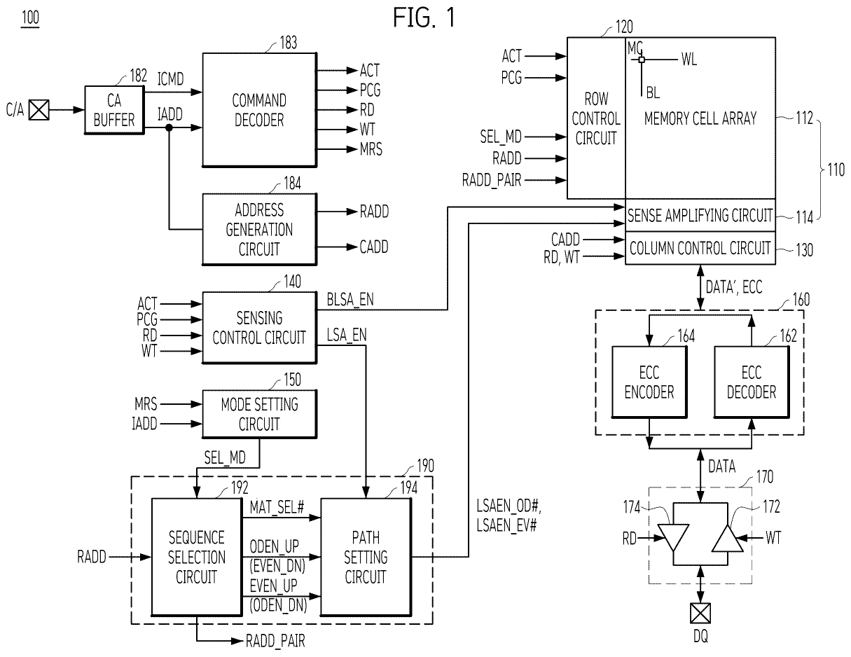

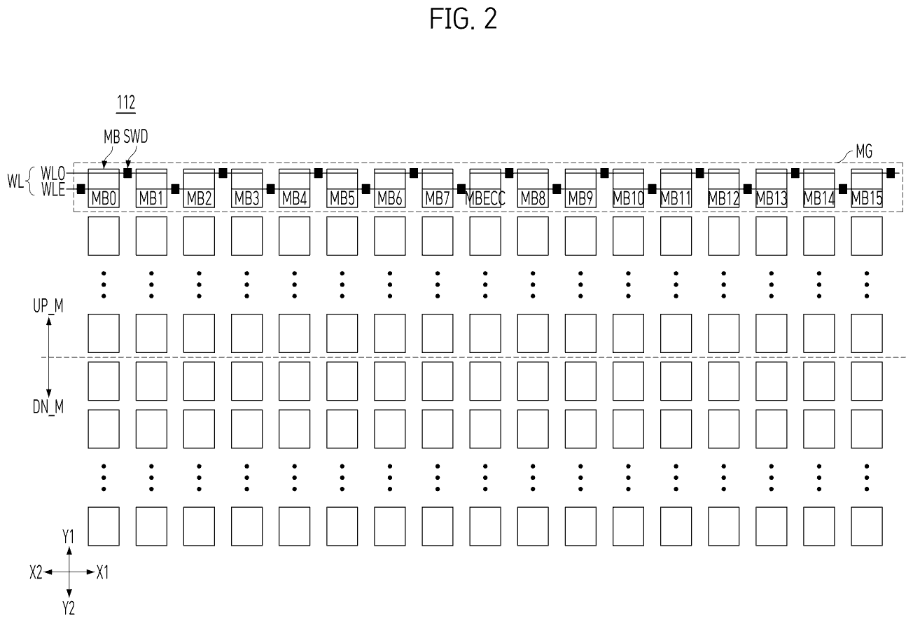

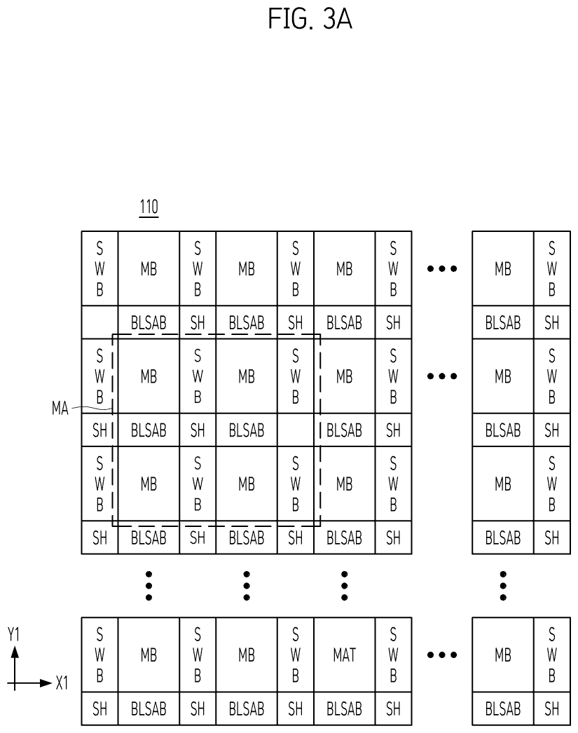

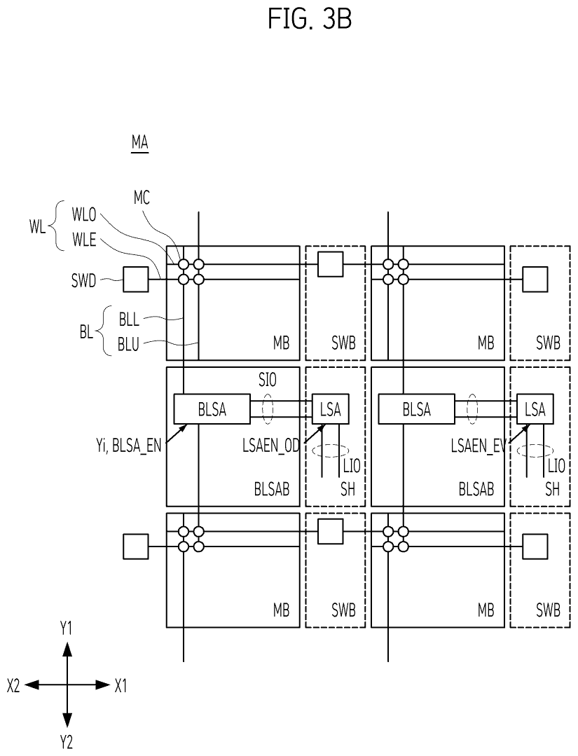

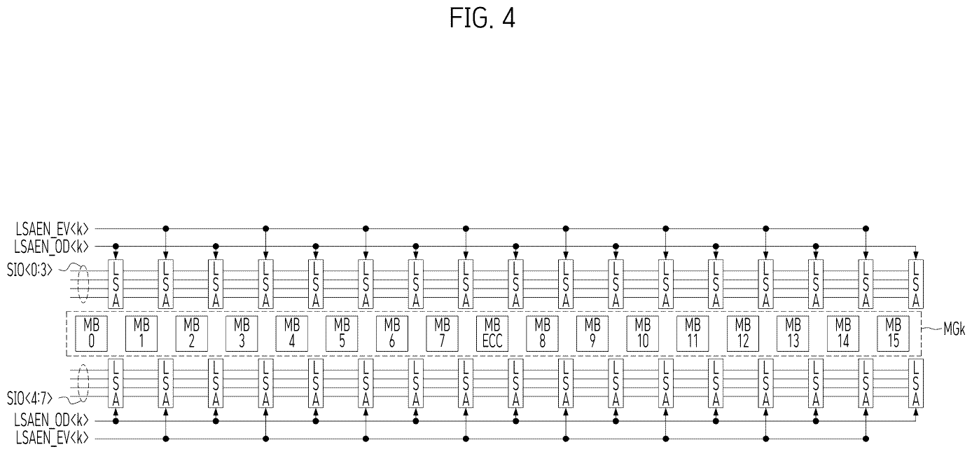

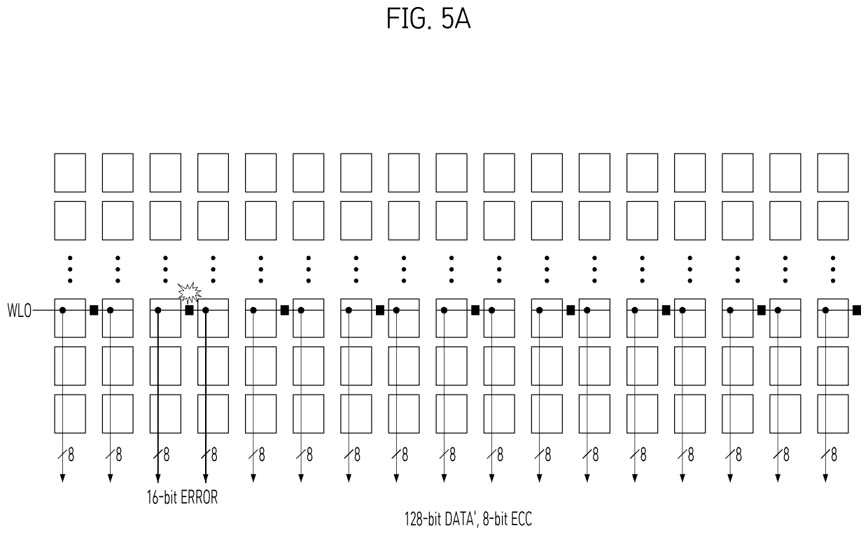

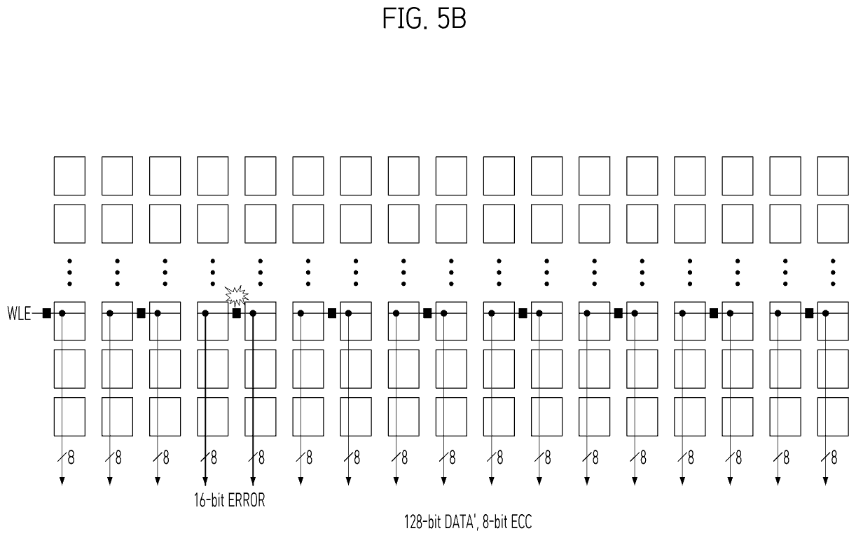

FIG. 1 is a block diagram illustrating a memory device according to an embodiment of the present disclosure. FIG. 2 is a diagram illustrating a memory cell array of FIG. 1 according to an embodiment of the present disclosure. FIGS. 3A and 3B are diagrams for explaining a core region of FIG. 1. FIG. 4 is a diagram illustrating local sense amplifiers allocated to one cell group according to an embodiment of the present disclosure. FIGS. 5A and 5B are diagrams for explaining error coverage faults of a sub-word line driver.

Referring to FIG. 1, a memory device 100 may include a memory cell array 112, a sense amplifying circuit 114, a row control circuit 120, a column control circuit 130, a sensing control circuit 140, a mode setting circuit 150, an error correction code (ECC) engine 160, a data input/output circuit 170, a command/address (CA) buffer 182, a command decoder 183, an address generation circuit 184, and a path control circuit 190. In an embodiment of the present disclosure, the memory cell array 112 and the sense amplifier circuit 114 may be defined as a core region 110. Also, the row control circuit 120 and the path control circuit 190 together may be referred to as a control circuit.

The memory cell array 112 may be coupled to the row control circuit 120 through a plurality of word lines WL, and may be coupled to the column control circuit 130 through a plurality of bit lines BL. The plurality of word lines WL may extend in a first direction (e.g., a row direction) and are sequentially arranged in a second direction (e.g., a column direction). The plurality of bit lines BL may extend in a column direction and are sequentially arranged in a row direction.

Meanwhile, in order to reduce delay in the delivery of a word line voltage, which increases as the number of memory cells connected to the word lines increases and a distance between the word lines decreases, one main word line may be divided into a plurality of sub-word lines (e.g., eight sub-word lines) and each sub-word line may be driven using sub-word line drivers. The plurality of word lines WL mentioned in the present disclosure may correspond to sub-word lines.

Referring to FIG. 2, the memory cell array 112 may include a plurality of memory blocks (hereinafter, referred to as “cell blocks MB”) arranged in an array form in a first direction X1 and a second direction Y1 intersecting the first direction X1. Each cell block MB may include a plurality of memory cells MC connected between a plurality of word lines WL and a plurality of bit lines BL. In an embodiment of the present disclosure, a “cell block” may be defined as a set of memory cells that share word lines WL and bit lines BL and are arranged in substantially the same manner.

A plurality of sub-word line drivers SWD may be disposed between the cell blocks MB disposed in the first direction X1. In FIG. 2, the filled squares between the cell blocks MB may represent the sub-word line drivers SWD, and the lines extending to the left and right of the sub-word line drivers SWD may represent the word lines (or sub-word lines). In reality, a much larger number of sub-word line drivers SWD and word lines exist, but only a part of the lines are shown here to illustrate a simple structure for illustrative purpose.

In an embodiment, the cell blocks MB disposed in the first direction X1 may form one cell group MG. That is, the cell blocks MB in one cell group MG may share the sub-word line drivers SWD in the first direction X1, and share bit line sense amplifiers with cell blocks MB in an adjacent cell group in the second direction Y1. One cell group MG may include a plurality of normal cell blocks MB0 to MB15 storing user data DATA′ and at least one parity cell block MBECC storing an error correction code ECC. For example, in one cell group MG, the first to eighth normal cell blocks MB0 to MB7, the parity cell block MBECC, and the ninth to 16-th normal cell blocks MB8 to MB15 may be sequentially disposed in the first direction X1 (i.e., the row direction). The plurality of cell blocks MB may be divided into upper cell blocks (or cell groups) UP_M positioned in an upper region of the memory cell array 112 in the second direction Y1, and lower cell blocks (or cell groups) DN_M positioned in a lower region of the memory cell array 112 in the second direction Y1. The upper cell groups UP_M and the lower cell groups DN_M may be disposed symmetrically to each other across a line of symmetry extending in the first direction X1.

Each of the cell blocks MB may include odd-numbered word lines (hereinafter, referred to as “first word lines WLO”) and even-numbered word lines (hereinafter, referred to as “second word lines WLE”) extending in the first direction X1 and alternating with each other in the second direction Y1. In odd-numbered cell blocks MB0, MB2, MB4, MB6, MBECC, MB9, MB11, MB13, and MB15, the first word lines WLO may share sub-word line drivers SWD with an adjacent cell block disposed in the first direction X1, and the second word lines WLE may share sub-word line drivers SWD with an adjacent cell block disposed in a direction X2, which is opposite to the first direction X1. Conversely, in even-numbered cell blocks MB1, MB3, MB5, MB7, MB8, MB10, MB12, and MB14, the second word lines WLE may share sub-word line drivers SWD with an adjacent cell block disposed in the first direction X1, and the first word lines WLO may share sub-word line drivers SWD with an adjacent cell block disposed in the direction X2. That is, since two adjacent cell blocks MB share a sub-word line driver SWD, one sub-word line driver SWD may be allocated to two adjacent cell blocks MB disposed in the first direction X1.

Meanwhile, bit line sense amplifiers (BLSA of FIG. 3B) and local sense amplifiers (LSA of FIG. 3B) may be disposed between cell blocks MB arranged in the second direction Y1, and these sense amplifiers may be included in the sense amplifier circuit 114 of FIG. 1.

Referring to FIG. 3A, the core region 110 including the memory cell array 112 and the sense amplifier circuit 114 of FIG. 1 is illustrated. Sub-word line driver regions SWB may be disposed between cell blocks MB disposed in the first direction X1. A plurality of sub-word line drivers may be disposed in the sub-word line driver region SWB. Bit line sense amplifier regions BLSAB may be disposed between cell blocks MB disposed in the second direction Y1. A plurality of bit line sense amplifiers may be disposed in the bit line sense amplifier region BLSAB. Meanwhile, a region where the sub-word line driver regions SWB intersect with the bit line sense amplifier region BLSAB may be defined as a sub-hole region SH. In the sub-hole region SH, local sense amplifiers for transferring data between segment lines SIO the local lines LIO may be disposed.

Referring to FIG. 3B, a partial area MA of FIG. 3A is shown.

Each of the cell blocks MB may include first word lines WLO and second word lines WLE extending in the first direction X1 and alternately disposed in the second direction Y1. Each of the cell blocks MB may include first bit lines BLU and second bit lines BLL extending in the second direction Y1 and alternately disposed in the first direction X1. The first bit lines BLU may share bit line sense amplifiers BLSA with an adjacent cell block disposed in the second direction Y1, and the second bit lines BLL may share bit line sense amplifiers BLSA with an adjacent cell block disposed in a direction Y2 opposite to the second direction Y1. That is, since two adjacent cell blocks MB arranged in the second direction Y1 share the bit line sense amplifiers BLSA, one bit line sense amplifier BLSA may be allocated to two adjacent cell blocks MB disposed in the second direction Y1.

The bit line sense amplifiers BLSA may be activated according to a bit line sensing control signal BLSA_EN to sense and amplify data of the bit lines BL, and may connect the bit lines BL and segment lines SIO according to a column selection signal Yi provided from the column control circuit (130 of FIG. 1). The local sense amplifiers LSA may sense and amplify data of the segment lines SIO, and transmit the data from the segment lines SIO to local lines LIO, or transmit data from the local lines LIO to the segment lines SIO, according to first and second local sensing control signals LSAEN_OD # and LSAEN_EV #, where “#” denotes the number of cell groups MG of FIG. 2. According to an embodiment, a data input/output direction of the local sense amplifiers LSA may be controlled in response to a read command RD or a write command WT. each of the first and second local sensing control signals LSAEN_OD # and LSAEN_EV # may be composed of bits corresponding to the respective cell groups MG. In an embodiment of the present disclosure, the local sense amplifiers LSA may be classified into odd-numbered local sense amplifiers LSA corresponding to odd-numbered cell blocks, and even-numbered local sense amplifiers LSA corresponding to even-numbered cell blocks. The odd-numbered local sense amplifiers LSA may be controlled by the first local sensing control signal LSAEN_OD #, and the even-numbered local sense amplifiers LSA may be controlled by the second local sensing control signal LSAEN_EV #.

Referring to FIG. 4, the local sense amplifiers LSA allocated to one exemplary cell group MGk are illustrated. Although FIG. 4 shows one local sense amplifier LSA connected to every four segment lines, in practice, one local sense amplifier LSA may be disposed for each segment line. For convenience of description, the local sense amplifier LSA is shown as being connected to segment lines SIO, but in practice, it may be disposed between the segment lines SIO and the local lines LIO. Furthermore, although FIG. 4 illustrates the segment lines SIO<0:7> in a single-ended form, each of the segment lines SIO<0:7> may actually be configured in a differential form.

In one cell group MG, the first to eighth normal cell blocks MB0 to MB7, the parity cell block MBECC, and the ninth to sixteenth normal cell blocks MB8 to MB15 may be sequentially arranged in a row direction. Four upper segment lines SIO<0:3> may be disposed above the cell blocks, and four lower segment lines SIO<4:7> may be disposed below the cell blocks. The odd-numbered local sense amplifiers LSA corresponding to the odd-numbered cell blocks MB0, MB2, MB4, MB6, MBECC, MB9, MB11, MB13, and MB15 may be controlled by a corresponding bit LSAEN_OD<k> of the first local sensing control signal LSAEN_OD #. The even-numbered local sense amplifiers LSA corresponding to the even-numbered cell blocks MB1, MB3, MB5, MB7, MB8, MB10, MB12, and MB14 may be controlled by a corresponding bit LSAEN_EV<k> of the second local sensing control signal LSAEN_EV #.

With the above configuration, when both the bit LSAEN_OD<k> of the first local sensing control signal LSAEN_OD # and the bit LSAEN_EV<k> of the second local sensing control signal LSAEN_EV # are at a high level, data may be output from all cell blocks MB0 to MB15 and MBECC included in the cell group MGk. On the other hand, when only the bit LSAEN_OD<k> of the first local sensing control signal LSAEN_OD # is at a high level, data may be output only from the odd-numbered cell blocks MB0, MB2, MB4, MB6, MBECC, MB9, MB11, MB13, and MB15. When only the bit LSAEN_EV<k> of the second local sensing control signal LSAEN_EV # is at a high level, data may be output only from the even-numbered cell blocks MB1, MB3, MB5, MB7, MB8, MB10, MB12, and MB14.

Referring back to FIG. 1, the row control circuit 120 may perform an active operation of activating a word line selected by a row address RADD in response to an active command ACT, and perform a precharge operation of precharging the activated word line in response to a precharge command PCG. Hereinafter, a word line selected by the row address RADD will be referred to as a target word line, and a word line selected by a paired row address RADD_PAIR will be referred to as a paired word line. In an embodiment, the row control circuit 120 may activate only the target word line, or may activate both the target word line and the paired word line, according to a mode selection signal SEL_MD. The row control circuit 120 may perform an active operation of activating both the target word line selected by the row address RADD in a single page condition (hereinafter, referred to as a normal condition) in which the mode selection signal SEL_MD has a logic low level. Further, The row control circuit 120 may perform an active operation of activating both the target word line and the paired word line in a double page condition in which the mode selection signal SEL_MD has a logic high level.

The column control circuit 130 may select some bit lines (e.g., 8) of the bit lines BL of the memory cell array 112 according to the column address CADD, perform a read operation of reading the data DATA′ and the error correction code ECC from the memory cells MC through the selected bit lines in response to the read command RD, and perform a write operation of writing the data DATA′ and the error correction code ECC to the memory cells MC through the selected bit lines in response to the write command WT. The column control circuit 130 may decode the column address CADD to generate the column selection signal Yi for selecting some bit lines and provide it to the sense amplifier circuit 114.

The ECC engine 160 may be configured to perform ECC operations using low density parity check (LDPC) code, Bose, Chaudhri, Hocquenghem (BCH) code, turbo code, Reed-Solomon code, convolution code, recursive systematic code (RSC), and coded modulation such as trellis-coded modulation (TCM), and block coded modulation (BCM).

In more detail, the ECC engine 160 may include an ECC encoder 162 and an ECC decoder 164. The ECC encoder 162 may be referred to as a parity generation circuit, and the ECC decoder 164 may be referred to as an error correction circuit. The ECC encoder 162 may generate the error correction code ECC by using data DATA transmitted from the data input/output circuit 170, during a write operation. The data DATA and the generated error correction code ECC may be transmitted to the column control circuit 130 and written to the memory cells MC. The ECC decoder 164 may receive the data DATA′ and the error correction code ECC read from the memory cells MC, correct an error in the data DATA′ using the error correction code ECC, and output error-corrected data DATA to the data input/output circuit 170, during a read operation.

The data input/output circuit 170 may receive data DQ from an external device (e.g., a memory controller), or transmit data DQ to the memory controller. The data input/output circuit 170 may include a data input circuit 172 and a data output circuit 174. The data input circuit 172 may receive the data DQ transmitted from the memory controller and transmit the data DQ to the ECC engine 160 as the data DATA, according to the write command WT. The data output circuit 174 may transmit the error-corrected data DATA by the ECC engine 160 as the data DQ to the memory controller, according to the read command RD.

The CA buffer 182 may receive a command/address signal C/A from the memory controller. The CA buffer 182 may buffer the command/address signal C/A to output an internal command ICMD and an internal address IADD.

The command decoder 183 may decode the internal command ICMD to generate the active command ACT, the precharge command PCG, the write command WT, the read command RD, and a mode setting command MRS. The active command ACT is a signal input when an active operation is instructed, the precharge command PCG is a signal input when a precharge operation is instructed, the write command WT is a signal input when a write operation is instructed, and the read command RD may be a signal input when a read operation is instructed. The mode setting command MRS is a signal for reading setting data corresponding to the internal address signal ICA, among setting data stored in the mode setting circuit 150.

The address generation circuit 184 may classify the internal address IADD received from the CA buffer 182 into the row address RADD and the column address CADD. The row address RADD may be an address for selecting one of the plurality of word lines WL, and the column address CADD may be an address for selecting some bit lines on which a read operation and a write operation are to be performed, from among the plurality of bit lines BL. Each of the row address RADD and the column address CADD may include multiple bits. According to an embodiment, the address generation circuit 184 may classify some bits of the internal address IADD into a row address RADD, and classify the remaining bits into a column address CADD. Alternatively, the address generation circuit 184 may classify the address into a row address RADD when an active operation is instructed as a result of decoding the command decoder 183, and classify the address as a column address CADD when a read and write operation is instructed.

The sensing control circuit 140 may generate the bit line sensing control signal BLSA_EN and a preliminary local sensing control signal LSA_EN in response to the active command ACT, the precharge command PCG, the read command RD, and the write command WT. The sensing control circuit 140 may adjust an activation timing of the bit line sensing control signal BLSA_EN according to a specification, during a row active period defined by the active command ACT and the precharge command PCG. For example, the sensing control circuit 140 may provide the bit line sensing control signal BLSA_EN to supply a power voltage to bit line sense amplifiers BLSA during the row active period. The sensing control circuit 140 may also adjust an activation timing of the preliminary local sensing control signal LSA_EN according to the read command RD or the write command WT.

The mode setting circuit 150 may store setting data for configuring internal operations and may read the setting data corresponding to the internal address signal ICA in response to the mode setting command MRS. The mode setting circuit 150 may include a known mode register set. Based on the retrieved setting data, the mode setting circuit 150 may determine whether the current operating environment of the memory device is in a normal condition or in a double page condition, and generate the mode selection signal SEL_MD. For example, the mode selection signal SEL_MD may have a logic high level under the double page condition requiring relatively high reliability, and may have a logic low level under the normal condition requiring relatively low-power consumption.

The path control circuit 190 may control data to be input/output from odd-numbered cell blocks included in a cell group where the target word line is located, and even-numbered cell blocks included in a cell group where the paired word line is located. Depending on an embodiment, the path control circuit 190 may control data to be input/output from even-numbered cell blocks included in the target word line group and odd-numbered cell blocks included in the paired word line group. The path control circuit 190 may include a sequence selection circuit 192 and a path setting circuit 194.

The sequence selection circuit 192 may generate the paired row address RADD_PAIR, a cell group selection signal MAT_SEL #, a first order control signal ODEN_UP (or EVEN_DN), and a second order control signal EVEN_UP (or ODEN_DN), based on the row address RADD input during an access operation. In an embodiment, the access operation may include an active operation performed on a row basis according to the row address, and subsequent read and write operations.

The sequence selection circuit 192 may generate the paired row address RADD_PAIR by inverting a specific bit of the row address RADD. For example, when a cell group MG is selected based on the upper bits of the row address RADD, the sequence selection circuit 192 may invert the most significant bit (MSB) of the row address RADD to generate the paired row address RADD_PAIR. Accordingly, when a target word line in the upper cell group UP_M is selected by the row address RADD, a paired word line in the lower cell group DN_M may be selected by the paired row address RADD_PAIR, and vice versa. The target word line and the paired word line may be symmetrically arranged in the upper and lower cell groups. As a result, the cell group containing the target word line and the cell group containing the paired word line do not share bit line sense amplifiers BLSA in a column direction.

The sequence selection circuit 192 may generate the cell group selection signal MAT_SEL # by decoding at least one of the upper bits of the row address RADD and the upper bits of the paired row address RADD_PAIR according to the mode selection signal SEL_MD. The cell group selection signal MAT_SEL # is a signal for designating the cell groups MG and may consist of bits corresponding respectively to the cell groups. In the normal condition where the mode selection signal SEL_MD has a logic low level, the sequence selection circuit 192 may decode the upper bits of the row address RADD to generate the cell group selection signal MAT_SEL #. In contrast, in the double page condition where the mode selection signal SEL_MD has a logic high level, the sequence selection circuit 192 may decode both the upper bits of the row address RADD and the upper bits of the paired row address RADD_PAIR to generate the cell group selection signal MAT_SEL #. Thus, only one bit of the cell group selection signal MAT_SEL # may be set to high in the normal condition, whereas two bits of the cell group selection signal MAT_SEL # may be set to high in the double page condition.

In the normal condition where the mode selection signal SEL_MD has a logic low level, the sequence selection circuit 192 may set both the first order control signal ODEN_UP (EVEN_DN) and the second order control signal EVEN_UP (ODEN_DN) to a specific level (e.g., a logic high level). On the other hand, in the double page condition where the mode selection signal SEL_MD has a logic high level, the sequence selection circuit 192 may activate only one of the first order control signal ODEN_UP (EVEN_DN) and the second order control signal EVEN_UP (ODEN_DN), according to the MSB of the row address RADD.

The first order control signal ODEN_UP (EVEN_DN) may include a first upper control signal ODEN_UP and a second lower control signal EVEN_DN, and the second order control signal EVEN_UP (ODEN_DN) may include a second upper control signal EVEN_UP and a first lower control signal ODEN_DN. The first upper control signal ODEN_UP and the second upper control signal EVEN_UP are signals for controlling data input/output in the upper cell groups UP_M, and the first lower control signal ODEN_DN and the second lower control signal EVEN_DN are signals for controlling data input/output in the lower cell groups DN_M. For convenience of explanation, the signals ODEN_UP (EVEN_DN) are described separately, but they may actually be combined into a single signal having the same logic level. Likewise, the signals EVEN_UP (ODEN_DN) may also be combined into a single signal with the same logic level.

The path setting circuit 194 may control data input/output of the cell blocks according to the cell group selection signal MAT_SEL #, the first order control signal ODEN_UP (EVEN_DN), and the second order control signal EVEN_UP (ODEN_DN).

As described in FIG. 2, among the plurality of cell blocks MB, adjacent cell blocks share sub-word line drivers SWD, so one sub-word line driver SWD may serve two cell blocks MB. For example, when 8-bit data is output per cell block, if the first word lines WLO are selected, 16-bit data may be output from the two adjacent cell blocks through one sub-word line driver SWD (see FIG. 5A); and if the second word lines WLE are selected, 16-bit data may also be output from the two adjacent cell blocks through the same sub-word line driver SWD (see FIG. 5B). That is, when a sub-word line is defective, an 8-bit error may occur; however, if a sub-word line driver SWD is defective, errors may simultaneously occur in both adjacent cell blocks, and thus up to 16 bits of error may result. When the ECC engine 160 only has an 8-bit error correction capability, an uncorrectable error UE may occur in such a case.

The path setting circuit 194 may control data input/output of the upper cell groups UP_M according to the cell group selection signal MAT_SEL #, the first upper control signal ODEN_UP, and the second upper control signal EVEN_UP, and control data input/output of the lower cell groups DN_M according to the cell group selection signal MAT_SEL #, the first lower control signal ODEN_DN, and the second lower control signal EVEN_DN. In this case, the path setting circuit 194 may control data to be input/output from odd-numbered cell blocks of the upper cell groups UP_M and even-numbered cell blocks of the lower cell groups DN_M, or from even-numbered cell blocks of the upper cell groups UP_M and odd-numbered cell blocks of the lower cell groups DN_M.

In an embodiment, the path setting circuit 194 may receive the preliminary local sensing control signal LSA_EN to generate the first and second local sensing control signals LSAEN_OD # and LSAEN_EV # corresponding to the preliminary local sensing control signal LSA_EN based on the cell group selection signal MAT_SEL #, the first order control signal ODEN_UP (EVEN_DN), and the second order control signal EVEN_UP (ODEN_DN). The local sense amplifiers LSA of the sense amplifier circuit 114 may be activated according to the first and second local sensing control signals LSAEN_OD # and LSAEN_EV #, and may control data input/output of the cell blocks during the read and write operations.

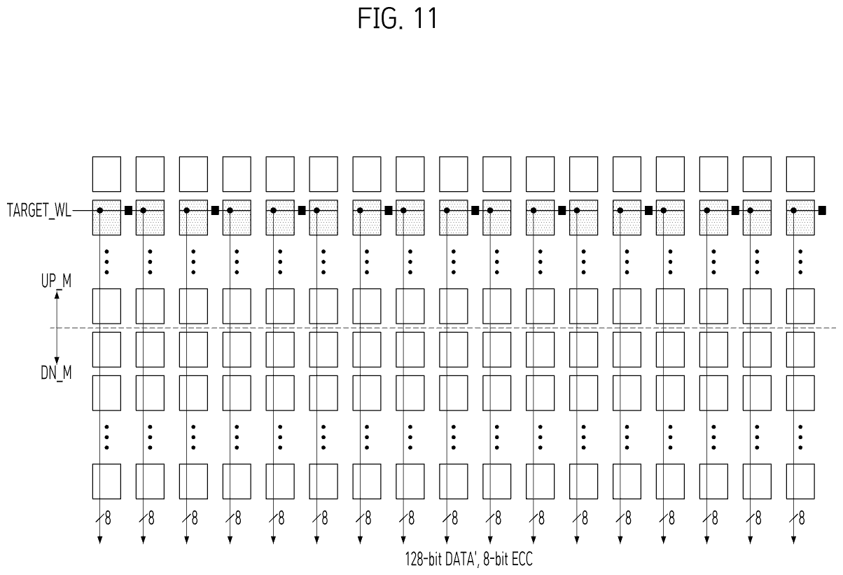

As described above, in an embodiment of the present disclosure, under the normal condition, the row control circuit 120 may activate only the target word line, and the path control circuit 190 may control data to be input/output only from the cell blocks where the target word line is located. On the other hand, under the double page condition, the row control circuit 120 may activate both the target word line located in either the upper cell group UP_M or the lower cell group DN_M, and the paired word line located in the other group. That is, a page size defined by one word line may be doubled. Additionally, the path control circuit 190 may control data to be input/output from odd-numbered cell blocks of the selected upper cell group UP_M and even-numbered cell blocks of the selected lower cell group DN_M, or vice versa. As a result, by implementing a double page condition, the path control circuit 190 reduces the number of data bits output from cell blocks that share the same sub-word line driver SWD, as discussed further below with reference to FIGS. 11 to 13. Consequently, the memory device 100 may limit the maximum number of error bits caused by a fault in a sub-word line driver SWD within the error correction capability range of the ECC engine, thereby preventing the occurrence of uncorrectable errors UE.

Hereinafter, specific embodiments of the present disclosure will be described with reference to the drawings.

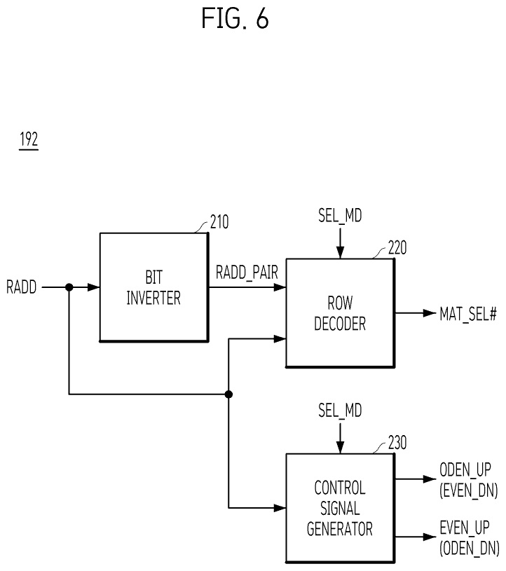

FIG. 6 is a block diagram illustrating a sequence selection circuit of FIG. 1.

Referring to FIG. 6, a sequence selection circuit 192 may include a bit inverter 210, a row decoder 220, and a control signal generator 230.

The bit inverter 210 may generate the paired row address RADD_PAIR by inverting the MSB of the row address RADD. For example, when the row address RADD of “010001” is inputted, the bit inverter 210 may generate the paired row address RADD_PAIR of “110001”.

The row decoder 220 may generate the cell group selection signal MAT_SEL # by decoding the upper bits of the row address RADD, when the mode selection signal SEL_MD is at a logic low level. On the other hand, when the mode selection signal SEL_MD is at a logic high level, the row decoder 220 may generate the cell group selection signal MAT_SEL # by decoding both the upper bits of the row address RADD and the upper bits of the paired row address RADD_PAIR.

The control signal generator 230 may activate both the first order control signal ODEN_UP (EVEN_DN) and the second order control signal EVEN_UP (ODEN_DN) to a logic high level when the mode selection signal SEL_MD is at a logic low level. The control signal generator 230 may activate only one of the first or second order control signals based on the MSB of the row address RADD, when the mode selection signal SEL_MD is at a logic high level. The control signal generator 230 may generate the first order control signal ODEN_UP (EVEN_DN) according to the MSB of the row address RADD, and may generate the second order control signal EVEN_UP (ODEN_DN) according to an inverted bit (i.e., an inverted MSB) of the MSB of the row address RADD. For example, when the MSB of the row address RADD is a high bit, the control signal generator 230 may activate the first order control signal ODEN_UP (EVEN_DN) to a logic high level and deactivate the second order control signal EVEN_UP (ODEN_DN) to a logic low level. Conversely, when the MSB of the row address RADD is a low bit, the control signal generator 230 may deactivate the first order control signal ODEN_UP (EVEN_DN) to a logic low level and activate the second order control signal EVEN_UP (ODEN_DN) to a logic high level. In an embodiment, the control signal generator 230 may include an inverter that inverts the MSB of the row address RADD based on the mode selection signal SEL_MD. However, the present invention is not limited thereto, and in some embodiments, the control signal generator 230 may generate the first order control signal at a logic low level and the second order control signal at a logic high level when the MSB of the row address RADD is a high bit.

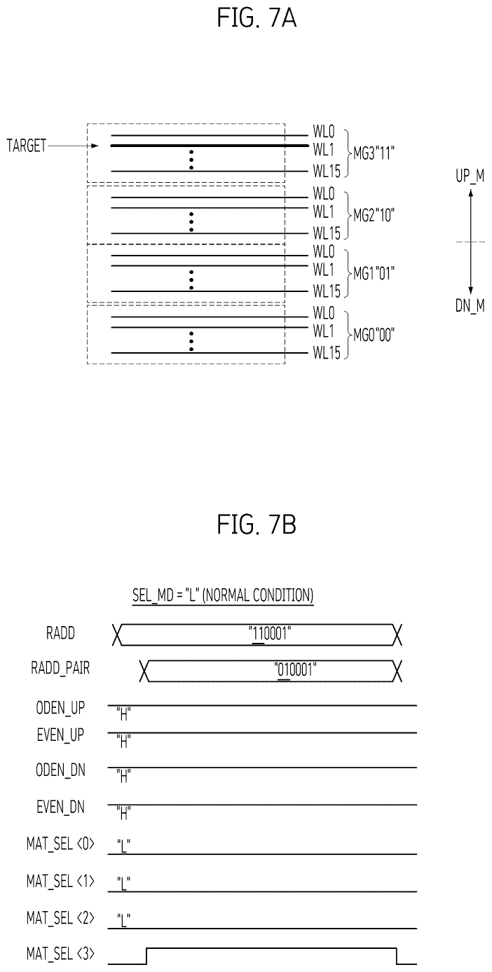

FIGS. 7A to 9B are diagrams for describing an operation of a sequence selection circuit of FIG. 6.

In FIGS. 7A to 9B, first to fourth cell groups MG0 to MG3 are arranged, and first to sixteenth word lines WL0 to WL15 are sequentially arranged in each cell group. The first and second cell groups MG0 and MG1 may be included in the lower cell groups DN_M, and the third and fourth cell groups MG2 and MG3 may be included in the upper cell groups UP_M. The row address RADD may be composed of upper 2 bits allocated for designating one of the first to fourth cell groups MG0 to MG3, and lower 4 bits allocated for designating one of the first to sixteenth word lines WL0 to WL15.

Referring to FIGS. 7A and 7B, an operation under a normal condition in which the mode selection signal SEL_MD is set to a logic low level is illustrated. According to the row address RADD of “110001” input during an access operation, the second word line WL1 of the fourth cell group MG3 may be designated as a target word line. The row decoder 220 may decode the upper bits of the row address RADD to generate the cell group selection signal MAT_SEL #. In this case, among the bits of the cell group selection signal MAT_SEL #, only the fourth bit MAT_SEL<3> corresponding to the fourth cell group MG3 may be set to a high bit. The control signal generator 230 may activate both the first order control signal ODEN_UP (EVEN_DN) and the second order control signal EVEN_UP (ODEN_DN) to a logic high level, regardless of the MSB of the row address RADD.

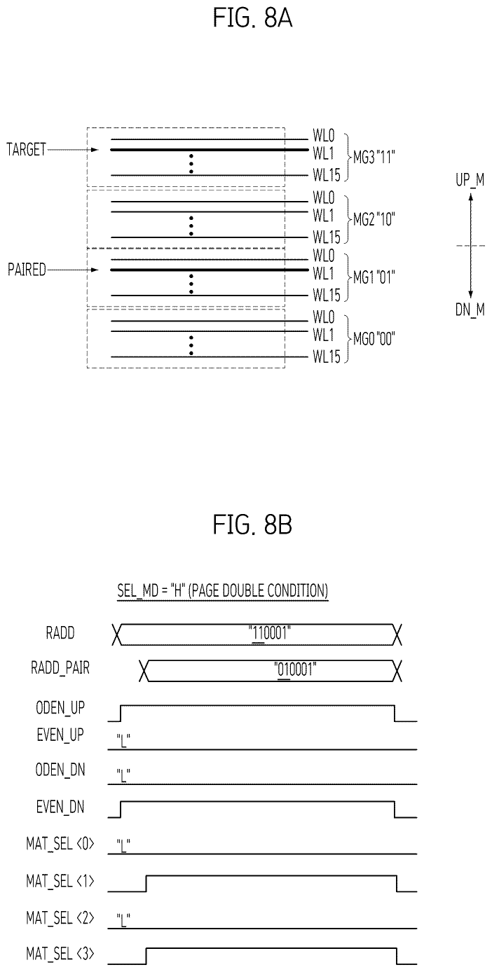

Referring to FIGS. 8A and 8B, an operation under a double page condition in which the mode selection signal SEL_MD is set to a logic high level is illustrated. According to the row address RADD of “110001” input during an access operation, the second word line WL1 of the fourth cell group MG3 may be designated as a target word line. When the row address RADD of “110001” is input, the bit inverter 210 may generate the paired row address RADD_PAIR of “010001”. Accordingly, the second word line WL1 of the second cell group MG1 may be designated as a paired word line. The row decoder 220 may decode the upper bits of both the row address RADD and the paired row address RADD_PAIR to generate the cell group selection signal MAT_SEL #. In this case, among the bits of the cell group selection signal MAT_SEL #, both the second bit MAT_SEL<1> corresponding to the second cell group MG1 and the fourth bit MAT_SEL<3> corresponding to the fourth cell group MG3 may be set to a high bit. Since the MSB of the row address RADD is a high bit, the control signal generator 230 may activate the first order control signal ODEN_UP (EVEN_DN) to a logic high level and deactivate the second order control signal EVEN_UP (ODEN_DN) to a logic low level.

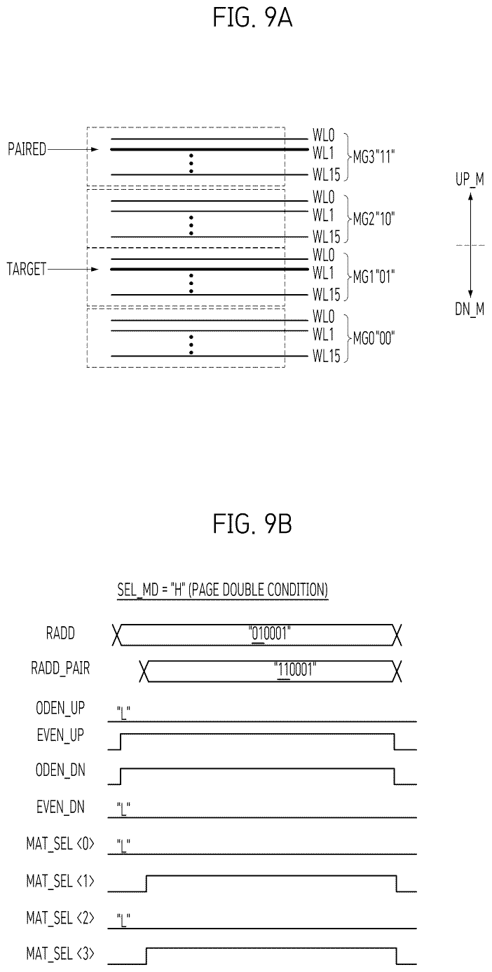

Referring to FIGS. 9A and 9B, an operation under a double page condition in which the mode selection signal SEL_MD is set to a logic high level is illustrated. According to the row address RADD of “010001” input during an access operation, the second word line WL1 of the second cell group MG1 may be designated as a target word line. When the row address RADD of “010001” is input, the bit inverter 210 may generate the paired row address RADD_PAIR of “110001”. Accordingly, the second word line WL1 of the fourth cell group MG3 may be designated as a paired word line. In this case, among the bits of the cell group selection signal MAT_SEL #, both the second bit MAT_SEL<1> corresponding to the second cell group MG1 and the fourth bit MAT_SEL<3> corresponding to the fourth cell group MG3 may be set to high. Since the MSB of the row address RADD is a low bit, the control signal generator 230 may deactivate the first order control signal ODEN_UP (EVEN_DN) to a logic low level and activate the second order control signal EVEN_UP (ODEN_DN) to a logic high level.

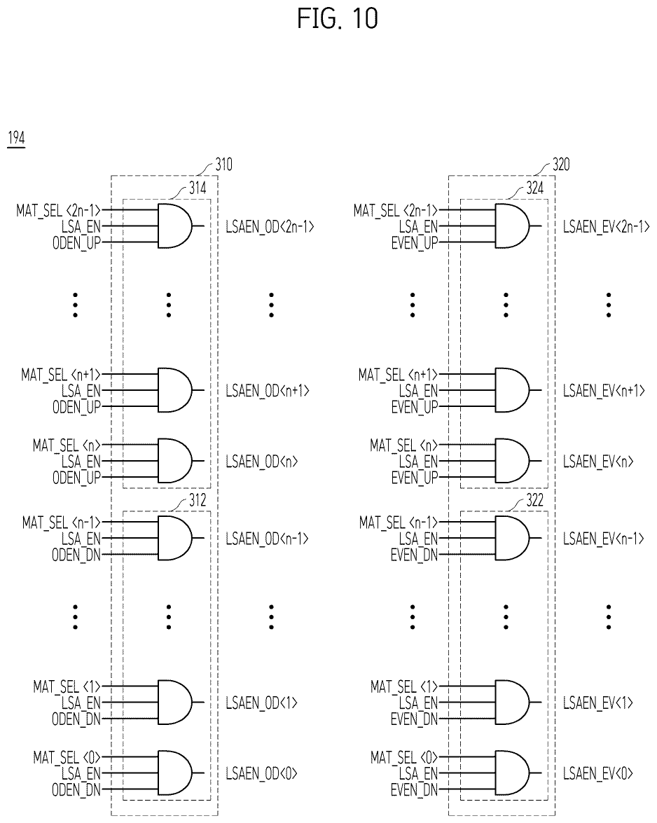

FIG. 10 is a block diagram illustrating a path setting circuit of FIG. 1.

Referring to FIG. 10, the path setting circuit 194 may include a first path controller 310 for generating the first local sensing control signal LSAEN_OD #, and a second path controller 320 for generating the second local sensing control signal LSAEN_EV #. In FIG. 10, it is assumed that each of the upper cell groups UP_M and the lower cell groups DN_M includes n groups, and the cell group selection signal MAT_SEL<0:2n−1> is composed of 2n bits to designate the upper cell groups UP_M and the lower cell groups DN_M.

The first path controller 310 may include a first lower control circuit 312 and a first upper control circuit 314. The first lower control circuit 312 may generate lower bits LSAEN_OD<0:n−1> of the first local sensing control signal LSAEN_OD # according to the lower bits MAT_SEL<0:n−1> of the cell group selection signal MAT_SEL #, the preliminary local sensing control signal LSA_EN, and the first lower control signal ODEN_DN. The first upper control circuit 314 may generate upper bits LSAEN_OD<n:2n−1> of the first local sensing control signal LSAEN_OD # according to the upper bits MAT_SEL<n:2n−1> of the cell group selection signal MAT_SEL #, the preliminary local sensing control signal LSA_EN, and the first upper control signal ODEN_UP.

The second path controller 320 may include a second lower control circuit 322 and a second upper control circuit 324. The second lower control circuit 322 may generate lower bits LSAEN_EV<0:n−1> of the second local sensing control signal LSAEN_EV # according to the lower bits MAT_SEL<0:n−1> of the cell group selection signal MAT_SEL #, the preliminary local sensing control signal LSA_EN, and the second lower control signal EVEN_DN. The second upper control circuit 324 may generate upper bits LSAEN_EV<n:2n−1> of the second local sensing control signal LSAEN_EV # according to the upper bits MAT_SEL<n:2n−1> of the cell group selection signal MAT_SEL #, the preliminary local sensing control signal LSA_EN, and the second upper control signal EVEN_UP.

Hereinafter, a data input/output operation according to an embodiment of the present disclosure will be described with reference to the drawings.

FIGS. 11 to 13 are diagrams illustrating data input/output operations according to an embodiment of the present disclosure. In FIGS. 11 to 13, for convenience of description, a data output operation during a data input/output operation is exemplarily shown.

Referring to FIG. 11, an example is illustrated in which a target word line TARGET_WL arranged in the upper cell groups UP_M is selected under a normal condition.

As described in FIGS. 7A and 7B, the sequence selection circuit 192 may activate both the first order control signal ODEN_UP (EVEN_DN) and the second order control signal EVEN_UP (ODEN_DN) to a logic high level. In addition, the sequence selection circuit 192 may set, among the bits of the cell group selection signal MAT_SEL #, only a bit designating a cell group (hereinafter referred to as a target cell group) in which the target word line TARGET_WL is arranged, to a high bit. The path setting circuit 194 may activate respective bits of the first local sensing control signal LSAEN_OD # and the second local sensing control signal LSAEN_EV # for designating the target cell group, according to the high bit of the cell group selection signal MAT_SEL #. Accordingly, data including 128-bit DATA′ and 8-bit ECC may be output from the cell blocks included in the target cell group.

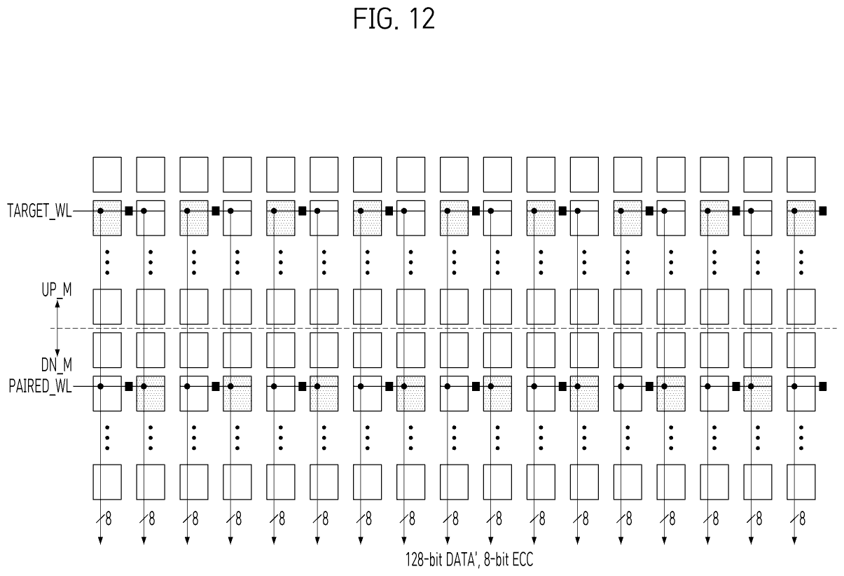

Referring to FIG. 12, an example is illustrated in which a target word line TARGET_WL arranged in the upper cell groups UP_M is selected under a double page condition.

As described in FIGS. 8A and 8B, the sequence selection circuit 192 may activate the first order control signal ODEN_UP (EVEN_DN) to a logic high level and deactivate the second order control signal EVEN_UP (ODEN_DN) to a logic low level. In addition, the sequence selection circuit 192 may set, among the bits of the cell group selection signal MAT_SEL #, two bits designating a target cell group and a cell group (hereinafter referred to as a paired cell group) in which the paired word line PAIRED_WL is arranged, to a high bit. At this time, one upper bit of the cell group selection signal MAT_SEL # may be activated to designate the target cell group included in the upper cell groups UP_M, and one lower bit of the cell group selection signal MAT_SEL # may be activated to designate the paired cell group included in the lower cell groups DN_M.

The first upper control circuit 314 of the path setting circuit 194 may set one upper bit of the first local sensing control signal LSAEN_OD # to a high bit according to one upper bit of the cell group selection signal MAT_SEL #, the preliminary local sensing control signal LSA_EN, and the first upper control signal ODEN_UP. In addition, the second lower control circuit 322 of the path setting circuit 194 may set one lower bit of the second local sensing control signal LSAEN_EV # to a high bit according to one lower bit of the cell group selection signal MAT_SEL #, the preliminary local sensing control signal LSA_EN, and the second lower control signal EVEN_DN.

Accordingly, 64-bit DATA′ and 8-bit ECC may be output from odd-numbered cell blocks included in the target cell group, and data 64-bit DATA′ may be output from the even-numbered cell blocks included in the paired cell group, such that a total of 128-bit DATA′ and 8-bit ECC may ultimately be output. At this time, the 8-bit error correction code ECC may be output from the parity cell block MBECC included in the target cell group. However, the present invention is not limited thereto, and according to an embodiment, 64-bit DATA′ and 8-bit ECC may be output from the odd-numbered cell blocks included in the paired cell group, and 64-bit DATA′ may be output from the even-numbered cell blocks included in the target cell group, such that 128-bit DATA′ and 8-bit ECC may ultimately be output, and the 8-bit error correction code ECC may be output from the parity cell block MBECC included in the paired cell group.

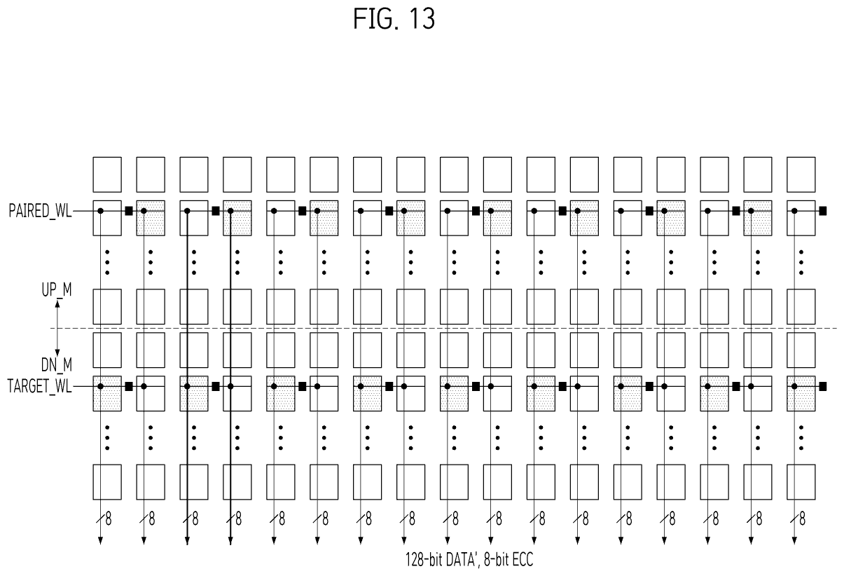

Referring to FIG. 13, an example is illustrated in which a target word line TARGET_WL arranged in the lower cell groups DN_M is selected under a double page condition.

As described in FIGS. 9A and 9B, the sequence selection circuit 192 may activate the first order control signal ODEN_UP (EVEN_DN) to a logic low level and deactivate the second order control signal EVEN_UP (ODEN_DN) to a logic high level. In addition, the sequence selection circuit 192 may set, among the bits of the cell group selection signal MAT_SEL #, two bits designating a target cell group and a paired cell group, to a high bit. At this time, one lower bit of the cell group selection signal MAT_SEL # may be activated to designate the target cell group included in the lower cell groups DN_M, and one upper bit of the cell group selection signal MAT_SEL # may be activated to designate the paired cell group included in the upper cell groups UP_M.

The first lower control circuit 312 of the path setting circuit 194 may set one lower bit of the first local sensing control signal LSAEN_OD # to a high bit according to one lower bit of the cell group selection signal MAT_SEL #, the preliminary local sensing control signal LSA_EN, and the first lower control signal ODEN_DN. In addition, the second upper control circuit 324 of the path setting circuit 194 may set one upper bit of the second local sensing control signal LSAEN_EV # to a high bit according to one upper bit of the cell group selection signal MAT_SEL #, the preliminary local sensing control signal LSA_EN, and the second upper control signal EVEN_UP.

Accordingly, 64-bit DATA′ and 8-bit ECC may be output from odd-numbered cell blocks included in the target cell group, and data 64-bit DATA′ may be output from the even-numbered cell blocks included in the paired cell group, such that a total of 128-bit DATA′ and 8-bit ECC may ultimately be output. At this time, the 8-bit error correction code ECC may be output from the parity cell block MBECC included in the target cell group.

In the embodiments of FIGS. 11 to 13, the target word line TARGET_WL is an odd-numbered word line WLO and described as an example. However, the present invention is not limited thereto, and the same operation may also be performed when the target word line TARGET_WL is an even-numbered word line WLE.

In accordance with an embodiment of the present disclosure, the mode selection signal SEL_MD is set to a logic low level when a low-power operation is required, and the memory device 100 may operate in a normal condition to minimize power consumption. On the other hand, the mode selection signal SEL_MD is set to a logic high level when high reliability is required, and the memory device 100 may operate under a double page condition. The memory device 100 may simultaneously activate the target word line corresponding to the row address RADD and the paired word line corresponding to the paired row address RADD_PAIR, thereby increasing the page size, and may control data to be input/output from odd-numbered cell blocks in the target cell group and even-numbered cell blocks in the paired cell group. Accordingly, the number of data bits output through the same, shared sub-word line driver may be reduced (e.g., from 16-bits to 8-bits), while the error coverage of the ECC engine 160 within the memory device 100 may be extended from the sub-word line level to the sub-word line driver level, without decreasing the total amount of data of the operation. As a result, by limiting the maximum number of error bits that may occur due to a fault in a sub-word line driver within the error correction capability range of the ECC engine, it is possible to prevent the occurrence of uncorrectable errors UE and to maximize error correction capability.

In the above embodiment, a memory device is configured with a single bank as an example. However, the present invention is not limited thereto. According to other embodiments, the memory device may be divided into a plurality of banks. In the following embodiment, a method of applying a double page condition to some of the banks among a plurality of banks will be described.

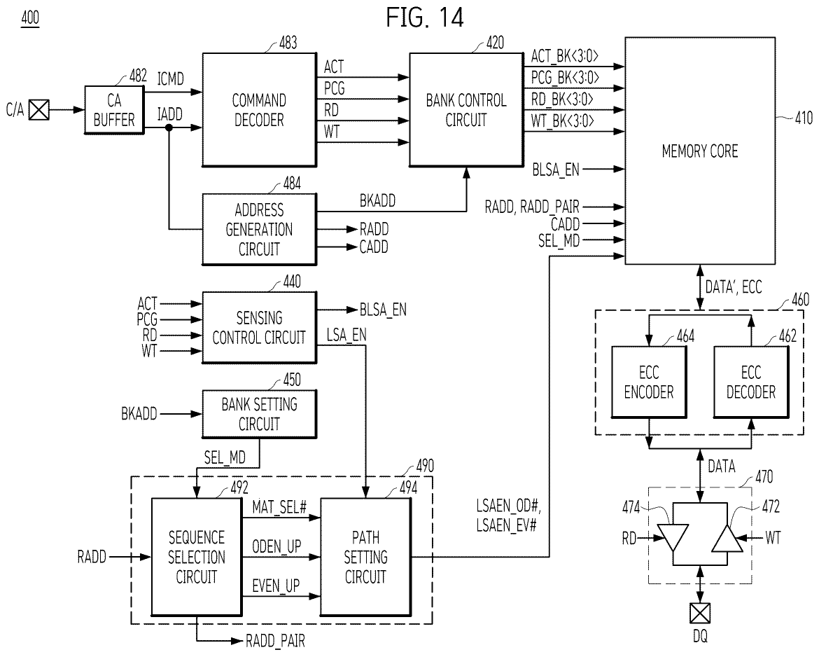

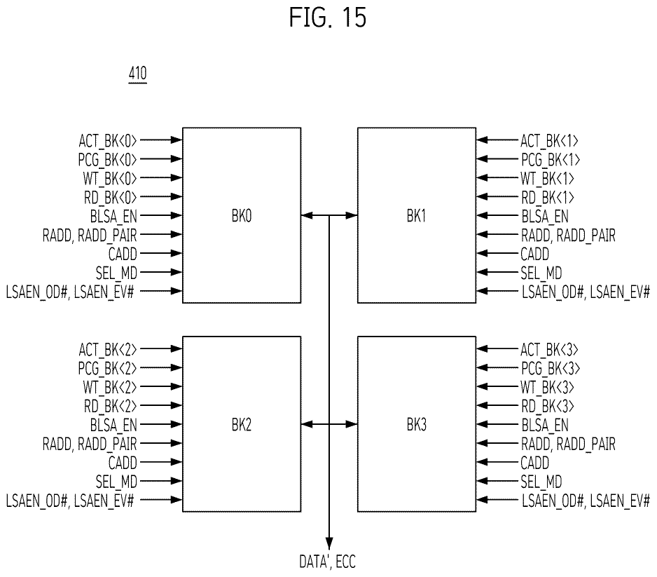

FIG. 14 is a block diagram of a memory device according to another embodiment of the present disclosure. FIG. 15 is a detailed configuration diagram of a memory core of FIG. 14.

Referring to FIG. 14, a memory device 400 may include the memory core 410, a bank control circuit 420, a sensing control circuit 440, a bank setting circuit 450, an error correction code (ECC) engine 460, a data input/output circuit 470, a command/address (CA) buffer 482, a command decoder 483, an address generation circuit 484, and a path control circuit 490. The ECC engine 460 may include an ECC encoder 462 and an ECC decoder 464, and the data input/output circuit 470 may include a data input circuit 472 and a data output circuit 474. The configurations of the sensing control circuit 440, the ECC engine 460, the data input/output circuit 470, the CA buffer 482, the command decoder 483, and the path control circuit 490 in FIG. 14 may be substantially the same as the configurations shown in FIG. 1.

The memory core 410 may include first to fourth banks (BK0 to BK3 in FIG. 15). Each of the first to fourth banks BK0 to BK3 may include components corresponding to a memory cell array (112 in FIG. 1) in which a plurality of memory cells MC connected to a plurality of word lines WL and a plurality of bit lines BL are arranged in an array form, a row control circuit (120 in FIG. 1), and a column control circuit (130 in FIG. 1). As described in FIG. 2, each bank BK0 to BK3 may include a plurality of cell blocks MB arranged in an array form in a first direction X1 and a second direction Y1 that intersects the first direction X1, and may include sub-word line drivers SWD alternately placed between the cell blocks MB arranged in the first direction X1. The cell blocks MB arranged in the first direction X1 may form one cell group MG, and the cell blocks MB within one cell group MG may share the sub-word line drivers SWD in the first direction X1 and share bit line sense amplifiers with cell blocks MB within an adjacent cell blocks in the second direction Y1.

Referring to FIG. 15, each of the first to fourth banks BK0 to BK3 may perform an active operation that selectively activates a word line (hereinafter referred to as a target word line) selected by a row address RADD, and a word line (hereinafter referred to as a paired word line) selected by a paired row address RADD_PAIR, when a corresponding bank active signal among bank active signals ACT_BK<0:3> is activated. In an embodiment, each of the first to fourth banks BK0 to BK3 may activate only the target word line or both the target word line and the paired word line, according to the mode selection signal SEL_MD. Each of the first to fourth banks BK0 to BK3 may perform an active operation of activating only the target word line under a single page condition (hereinafter referred to as a normal condition) when the mode selection signal SEL_MD is at a logic low level; and perform an active operation of activating both the target word line and the paired word line under a double page condition where the mode selection signal SEL_MD is at a logic high level.

Each of the first to fourth banks BK0 to BK3 may perform a precharge operation of deactivating the activated word line when a corresponding bank precharge signal among bank precharge signals PCG_BK<0:3> is activated. Each of the first to fourth banks BK0 to BK3 may perform a write operation of writing data DATA′ and error correction code ECC to the memory cells connected to bit lines selected by a column address CADD and the activated word line, when a corresponding bank write signal among bank write signals WT_BK<0:3> is activated. Each of the first to fourth banks BK0 to BK3 may perform a read operation of reading data DATA′ and error correction code ECC from the memory cells connected to bit lines selected by the column address CADD and the activated word line, when a corresponding bank read signal among bank read signals RD_BK<0:3> is activated. Bit line sense amplifiers BLSA included in each of the banks BK0 to BK3 may perform sensing and amplification operations according to a bit line sensing control signal BLSA_EN, and local sense amplifiers LSA included in each of the banks BK0 to BK3 may transfer data between segment lines SIO and local lines LIO according to first and second local sensing control signals LSAEN_OD # and LSAEN_EV #.

Referring back to FIG. 14, the address generation circuit 484 may classify an internal address IADD received from the CA buffer 482, into a bank address BKADD, the row address RADD, and the column address CADD. The bank address BKADD is an address for selecting one of the first to fourth banks BK0 to BK3 of the memory core 410, the row address RADD is an address for selecting one of the plurality of word lines WL within a bank, and the column address CADD is an address for selecting bit lines on which read and write operations will be performed within a bank. Each of the addresses BKADD, RADD, and CADD may be multi-bit values.

The bank control circuit 420 may decode the bank address BKADD to generate the bank active signals ACT_BK<0:3>, the bank precharge signals PCG_BK<0:3>, the bank write signals WT_BK<0:3>, and the bank read signals RD_BK<0:3> respectively corresponding to the first to fourth banks BK0 to BK3. The bank control circuit 420 may activate a bank active signal corresponding to a bank selected by the bank address BKADD, among the bank active signals ACT_BK<0:3>, in response to the active command ACT, and may activate a bank precharge signal corresponding to a bank selected by the bank address BKADD, among the bank precharge signals PCG_BK<0:3>, in response to the precharge command PCG. In addition, the bank control circuit 420 may activate a bank write signal corresponding to a bank selected by the bank address BKADD, among the bank write signals WT_BK<0:3>, in response to the write command WT, and may activate a bank read signal corresponding to a bank selected by the bank address BKADD, among the bank read signals RD_BK<0:3>, in response to the read command RD.

The bank setting circuit 450 may store, in advance, information (i.e., bank addresses) on specific banks to which the double page condition is to be applied. The bank setting circuit 450 may compare the stored bank information with the bank address BKADD provided from the address generation circuit 484, and set the mode selection signal SEL_MD to a logic high level when they match. Meanwhile, the bank setting circuit 450 may store information indicating that the double page condition is applied to all banks, or that the normal condition is to be applied to all banks.

According to an embodiment, the bank setting circuit 450 may include a non-volatile memory such as an anti-fuse, an e-fuse array (ARE), NAND flash memory, NOR flash memory, EPROM, or EEPROM. The bank setting circuit 450 may permanently store bank information in the non-volatile memory, and transfer the bank information stored in the non-volatile memory to a separate latch circuit during power-up. According to another embodiment, the bank setting circuit 450 may be configured using volatile memory such as DRAM or flip-flops. The bank information stored in the bank setting circuit 450 may be reset upon power-off, and new bank information may be set during power-up or during operation. To set new bank information, either existing commands or newly defined commands may be used. According to another embodiment, the bank setting circuit 450 may be configured as a known mode register set. The bank information may be stored in and read from the mode register set using a mode setting command.

The path control circuit 490 may control data to be input/output from odd-numbered cell blocks included in the cell group where the target word line is arranged, and from even-numbered cell blocks included in the cell group where the paired word line is arranged. The path control circuit 490 may include a sequence selection circuit 492 and a path setting circuit 494. The sequence selection circuit 492 may generate the paired row address RADD_PAIR, a cell group selection signal MAT_SEL #, a first order control signal ODEN_UP, and a second order control signal EVEN_UP, based on the row address RADD input during an access operation. The path setting circuit 494 may control data input/output of the upper cell groups UP_M and the lower cell groups DN_M according to the cell group selection signal MAT_SEL #, the first order control signal ODEN_UP, and the second order control signal EVEN_UP.

Hereinafter, an operation of the memory device 400 of FIG. 14 will be described in which a bank setting circuit 450 stores information regarding the second bank BK1 as an example.

When a bank address BKADD provided from a memory controller during an access operation does not designate the second bank BK1, the bank setting circuit 450 may set the mode selection signal SEL_MD to a logic low level. Accordingly, the memory device 400 may operate under a normal condition. That is, the sequence selection circuit 492 may activate both the first order control signal ODEN_UP and the second order control signal EVEN_UP to a logic high level, and among the bits of the cell group selection signal MAT_SEL #, only a bit designating the target cell group in which the target word line TARGET_WL is arranged may be set to high (see FIG. 7B). The path setting circuit 494 may activate the respective bits of the first local sensing control signal LSAEN_OD # and the second local sensing control signal LSAEN_EV # for designating the target cell group, according to a high bit of the cell group selection signal MAT_SEL #. Accordingly, 128-bit DATA′ and 8-bit ECC may be output from the cell blocks included in the target cell group (see FIG. 11).

When the bank address BKADD provided from the memory controller during an access operation designates the second bank BK1, the bank setting circuit 450 may set the mode selection signal SEL_MD to a logic high level. Accordingly, the memory device 400 may operate under a double page condition.

When the target cell group is arranged in the upper cell groups UP_M, the sequence selection circuit 492 may activate the first order control signal ODEN_UP to a logic high level and deactivate the second order control signal EVEN_UP to a logic low level (see FIG. 8B). In addition, the sequence selection circuit 492 may set two bits of the cell group selection signal MAT_SEL # to a high bit, namely the two bits for designating the target cell group in which the target word line TARGET_WL is arranged and the paired cell group in which the paired word line PAIRED_WL is arranged (see FIG. 8B). The path setting circuit 494 may set one upper bit of the first local sensing control signal LSAEN_OD # to a high bit and one lower bit of the second local sensing control signal LSAEN_EV # to a high bit. Accordingly, 64-bit DATA′ and 8-bit ECC may be output from the odd-numbered cell blocks included in the target cell group, and 64-bit DATA′ may be output from the even-numbered cell blocks included in the paired cell group, such that a total of 128-bit DATA′ and 8-bit ECC may be output (see FIG. 12).

When the target cell group is arranged in the lower cell groups DN_M, the sequence selection circuit 492 may deactivate the first order control signal ODEN_UP to a logic low level and activate the second order control signal EVEN_UP to a logic high level (see FIG. 9B). In addition, the sequence selection circuit 492 may set two bits of the cell group selection signal MAT_SEL # to a high bit, the two bits for designating the target cell group in which the target word line TARGET_WL is arranged and the paired cell group in which the paired word line PAIRED_WL is arranged (see FIG. 9B). The path setting circuit 494 may set one lower bit of the first local sensing control signal LSAEN_OD # to a high bit and one upper bit of the second local sensing control signal LSAEN_EV # to a high bit. Accordingly, 64-bit DATA′ and 8-bit ECC may be output from the odd-numbered cell blocks included in the target cell group, and 64-bit DATA′ may be output from the even-numbered cell blocks included in the paired cell group, such that a total of 128-bit DATA′ and 8-bit ECC may be output (see FIG. 13).

As described above, according to another embodiment of the present disclosure, the memory device 400 may increase the error correction capability by controlling banks requiring high reliability to operate under a double page condition, thereby providing an optimized reliability, accessibility, and serviceability RAS operation. Further, the memory device 400 may minimize power consumption by controlling the remaining banks to operate under a normal condition. Accordingly, the memory device 400 may provide the optimized RAS operation while minimizing the power consumption.

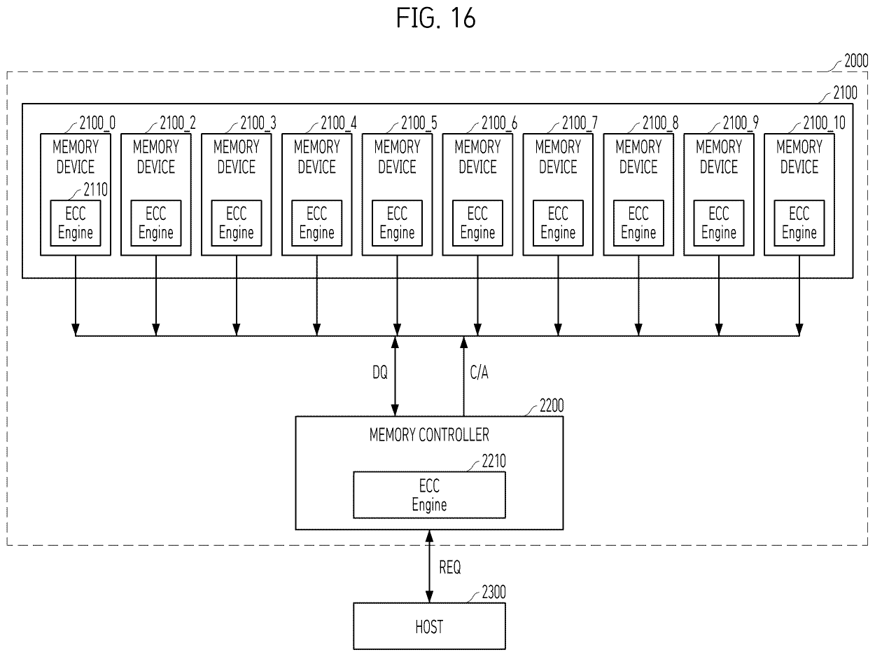

FIG. 16 is a block diagram illustrating a memory system including a memory module according to an embodiment of the present disclosure.

Referring to FIG. 16, a memory system 2000 may include a memory module 2100 and a memory controller 2200.

The memory controller 2200 may control operations of the memory system 2000 and control a data transfer between a host 2300 and the memory module 2100. The memory controller 2200 may generate a command/address signal C/A according to a request REQ from the host 2300 to provide the command/address signal C/A to the memory module 2100, and provide data DQ corresponding to the request REQ from the host 2300 to the memory module 2100, and provide data DQ read from the memory module 2100 to the host 2300.

The memory controller 2200 may include an error correction code (ECC) engine 2210. The ECC engine 2210 may detect and correct an error in the data DQ read from the memory module 2100 and provide error-corrected data to the host 2300. When the number of error bits of the data DQ exceeds an error correction capability of the ECC engine 2210, the memory controller 2200 may notify the host 2300 that an uncorrectable error (UE) has occurred.

The memory module 2100 may include a plurality of memory devices (MD) 2100_0 to 2100_10. Each of the memory devices 2100_0 to 2100_10 may include an ECC engine 2110. Each of the memory devices 2100_0 to 2100_10 may correspond to the memory device 100 described in FIG. 1 or the memory device 400 described in FIG. 14. That is, when an operating environment requires a double page condition, each of the memory devices 2100_0 to 2100_10 may simultaneously activate a target word line corresponding to a row address RADD and a paired word line corresponding to a row address RADD_PAIR, according to the row address RADD, thereby increasing the page size and controlling data to be input/output from odd-numbered cell blocks of a target cell group and even-numbered cell groups of a paired cell group. Accordingly, the error coverage of the ECC engine in the memory device may be extended from a sub-word line level to a sub-word line driver level by reducing the number of data bits output by a shared sub-word line driver. As a result, it is possible to prevent the occurrence of an uncorrectable errors (UE) and maximize the error correction capability by limiting the maximum number of error bits that may occur due to a fault of the sub-word line driver to within the error correction capability range of the ECC engine 2110.

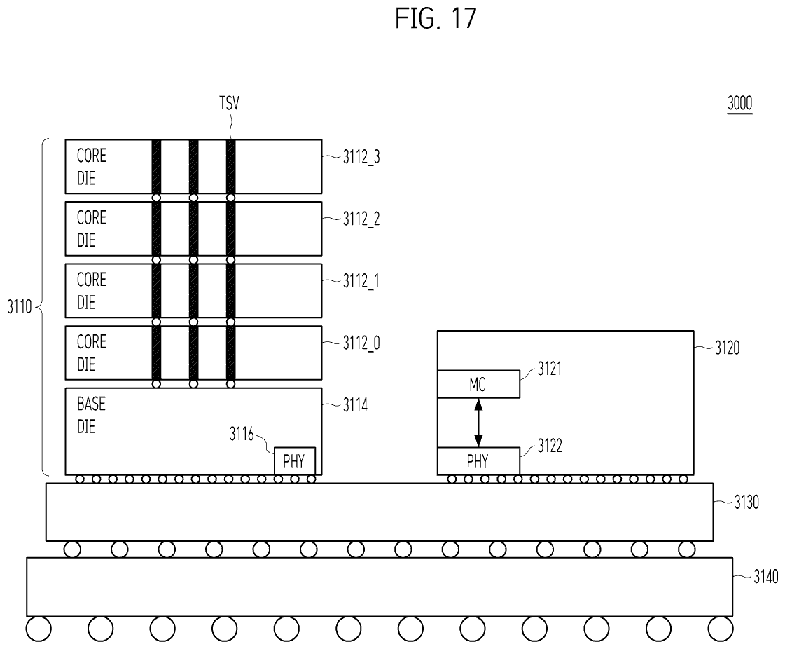

FIG. 17 is a block diagram illustrating a memory system including a stacked memory device according to an embodiment of the present disclosure.

Referring to FIG. 17, a memory system 3000 may include a package substrate 3140, an interposer 3130, a stacked memory device 3110, and a processor 3120.

The package substrate 3140 may include a printed circuit board (PCB). The package substrate 3140 may be electrically connected to an external system board, main board, or module board through bumps.

The interposer 3130 may be formed on the package substrate 3140. The interposer 3130 may be a silicon substrate in which only wiring is formed.

The stacked memory device 3110 and the processor 3120 may be formed on the interposer 3130. The stacked memory device 3110 and the processor 3120 may be disposed on the interposer 3130 and spaced apart from each other. Although one stacked memory device 3110 are illustrated in FIG. 17, the embodiments of the present disclosure are not limited thereto, and one or more stacked memory devices may be formed on the interposer 3130.

The processor 3120 may include a memory controller (MC) 3121 and a physical interface circuit (PHY) 3122. The memory controller 3121 may be configured to control the stacked memory device 3110. The physical interface circuit 3122 may interface between the memory controller 3121 and the stacked memory device 3110. The physical interface circuit 3122 may be an interface circuit that converts signals transferred from the memory controller 3121 into signals suitable for use in the stacked memory device 3110 and outputs the signals transferred from the stacked memory device 3110 into signals suitable for use in the memory controller 3121. The processor 3120 may be one of various processors such as a micro-processing unit (MPU), a central processing unit (CPU), a general processing unit (GPU), and a host processing unit (HPU).

Each of the stacked memory device 3110 may include a lower chip 3114 and one or more upper chips 3112_0 to 3112_3 vertically stacked on the interposer 3130. An example of the stacked memory device 3110 formed by stacking a plurality of chips as described above may be a high bandwidth memory (HBM). Through electrodes TSV are formed between the lower chip 3114 and the upper chips 3112_0 to 3112_3, through which signals (i.e., commands, addresses, and data) may be transferred between the chips.

The lower chip 3114 may include a physical interface circuit (PHY) 3116 for an interface with the memory controller. Each of the upper chips 3112_0 to 3112_3 may correspond to the memory device 100 described in FIG. 1 or the memory device 400 described in FIG. 14. That is, when an operating environment requires a double page condition, each of the upper chips 3112_0 to 3112_3 may simultaneously activate a target word line corresponding to a row address RADD and a paired word line corresponding to a row address RADD_PAIR, according to the row address RADD, thereby increasing the page size and controlling data to be input/output from odd-numbered cell blocks of a target cell group and even-numbered cell groups of a paired cell group. Accordingly, the error coverage of an ECC engine in the memory device may be extended from a sub-word line to a sub-word line driver by reducing the number of data bits output by a shared sub-word line driver. As a result, it is possible to prevent the occurrence of an uncorrectable error (UE) and maximize the error correction capability by limiting the maximum number of error bits that may occur due to a fault of the sub-word line driver to within the error correction capability range of the ECC engine.

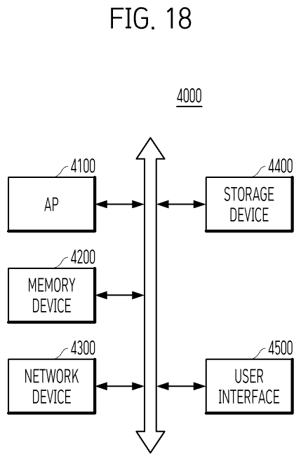

FIG. 18 is a block diagram illustrating a mobile system including a memory device according to an embodiment of the present disclosure.

Referring to FIG. 18, a mobile system 4000 may include an application processor (AP) 4100, a memory device 4200, a network device 4300, a storage device 4400, and a user interface 4500.

The application processor 4100 may drive components, an operating system (OS), or a user program included in the mobile system 4000. For example, the application processor 4100 may be provided as a system-on-chip (SoC).

The memory device 4200 may operate as a main memory, an operation memory, a buffer memory, or a cache memory of the mobile system 4000. The memory device 4200 may include a volatile random access memory such as DRAM, SDRAM, DDR SDRAM, DDR2 SDRAM, DDR3 SDRAM, LPDDR3 SDARM, LPDDR3 SDRAM, or a nonvolatile random access memory such as PRAM, ReRAM, MRAM, FRAM, etc. According to an embodiment, the memory device 4200 may be configured as a memory module 2100 described with reference to FIG. 16.

In an embodiment of the present disclosure, the memory device 4200 may correspond to a memory device 100 described in FIG. 1 or the memory device 400 described in FIG. 14. That is, when an operating environment requires a double page condition, the memory device 4200 may simultaneously activate a target word line corresponding to a row address RADD and a paired word line corresponding to a row address RADD_PAIR, according to the row address RADD, thereby increasing the page size and controlling data to be input/output from odd-numbered cell blocks of a target cell group and even-numbered cell groups of a paired cell group. Accordingly, the error coverage of an ECC engine in the memory device may be extended from a sub-word line level to a sub-word line driver level by reducing the number of data bits output by a shared sub-word line driver. As a result, it is possible to prevent the occurrence of an uncorrectable error (UE) and maximize the error correction capability by limiting the maximum number of error bits that may occur due to a fault of the sub-word line driver to within the error correction capability range of the ECC engine.

The network device 4300 may communicate with external devices. For example, the network device 4300 may support wireless communication such as Code Division Multiple Access (CDMA), Global System for Mobile Communication (GSM), Wideband CDMA (WCDMA), CDMA-2000, Time Division Multiple Access (TDMA), Long Term Evolution (LTE), Wimax, WLAN, UWB, Bluetooth, Wi-Fi, etc. For example, the network device 4300 may be included in the application processor 4100.

The storage device 4400 may store data. For example, the storage device 4400 may store data received from the application processor 4100. Alternatively, the storage device 4400 may transmit the stored data to the application processor 4100. For example, the storage device 4400 may be implemented as a nonvolatile semiconductor memory device such as a phase-change RAM (PRAM), a magnetic RAM (MRAM), a resistive RAM (RRAM), a NAND flash, a NAND flash, and a three-dimensional NAND flash.

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory device, comprising:
a plurality of cell blocks arranged in an array in a row direction and a column direction, and divided into cell groups that share a plurality of sub-word lines in the row direction; and
a control circuit configured to, during an access operation, activate a first sub-word line arranged in a first cell group and a second sub-word line arranged in a second cell group, among the cell groups, and control data to be input/output to/from odd-numbered cell blocks in the first cell group and even-numbered cell blocks in the second cell group, or to/from even-numbered cell blocks in the first cell group and odd-numbered cell blocks in the second cell group.

2. The memory device of claim 1,
wherein the cell groups are divided into upper cell groups and lower cell groups in the column direction, and
wherein the first cell group is included in one of the upper and lower cell groups, and the second cell group is included in the other one of the upper and lower cell groups.

3. The memory device of claim 1,
wherein the cell groups share bit line sense amplifiers with adjacent cell groups in the column direction, and
wherein the first cell group does not share bit line sense amplifiers with the second cell group.

4. The memory device of claim 1, wherein the control circuit is configured to:
activate the first sub-word line corresponding to a row address and activate the second sub-word line corresponding to a paired row address obtained by inverting a specific bit of the row address.

5. The memory device of claim 4, wherein the specific bit is a most significant bit (MSB) among bits of the row address, the bits designating the cell groups.

6. The memory device of claim 4, wherein the control circuit is configured to:
based on the row address, input/output data from the odd-numbered cell blocks in the first cell group and the even-numbered cell blocks in the second cell group, or input/output data from the even-numbered cell blocks in the first cell group and the odd-numbered cell blocks in the second cell group.

7. The memory device of claim 1, wherein the control circuit comprises:
a sequence selection circuit configured to generate a paired row address, a cell group selection signal, and first and second order control signals based on a row address during the access operation;
a row control circuit configured to activate the first sub-word line based on the row address and activate the second sub-word line based on the paired row address; and
a path setting circuit configured to control input/output of data according to the cell group selection signal and the first and second order control signals.

8. The memory device of claim 7, wherein the sequence selection circuit includes:
a bit inverter configured to generate the paired row address by inverting a specific bit of the row address;
a control signal generator configured to activate one of the first and second order control signals based on the specific bit of the row address; and
a row decoder configured to generate the cell group selection signal by decoding the row address and the paired row address.

9. The memory device of claim 7, wherein the path setting circuit includes:
a first path controller configured to generate lower bits of a first local sensing control signal based on lower bits of the cell group selection signal, a preliminary local sensing control signal, and the second order control signal, and generate upper bits of the first local sensing control signal based on upper bits of the cell group selection signal, the preliminary local sensing control signal, and the first order control signal; and
a second path controller configured to generate lower bits of a second local sensing control signal based on the lower bits of the cell group selection signal, the preliminary local sensing control signal, and the first order control signal, and generate upper bits of the second local sensing control signal based on the upper bits of the cell group selection signal, the preliminary local sensing control signal, and the second order control signal.

10. The memory device of claim 9, further comprising:
first local sense amplifiers activated based on respective bits of the first local sensing control signal, and configured to sense and amplify data between the odd-numbered cell blocks and data pads; and
second local sense amplifiers activated based on respective bits of the second local sensing control signal, and configured to sense and amplify data between the even-numbered cell blocks and the data pads.

11. The memory device of claim 9, wherein each of the cell groups comprises:
first to m-th normal cell blocks sequentially arranged in the row direction, where m is an integer greater than 1;
at least one ECC cell block; and
(m+1)-th to 2m-th normal cell blocks sequentially arranged in the row direction.

12. The memory device of claim 11, wherein the control circuit is configured to,
control parity data to be output from the ECC cell block arranged in the first cell group, when the row address designates the first sub-word line, and
control the parity data to be output from the ECC cell block arranged in the second cell group, when the row address designates the second sub-word line.

13. A memory device comprising:
a plurality of cell blocks arranged in an array in a row direction and a column direction, alternately sharing sub-word line drivers with adjacent cell blocks in the row direction;
a row control circuit configured to activate first sub-word line drivers corresponding to a row address, and activate second sub-word line drivers corresponding to a paired row address according to a mode selection signal, during an access operation; and
a path control circuit configured to control data to be input/output from odd-numbered cell blocks among cell blocks sharing the activated first sub-word line drivers, and even-numbered cell blocks among cell blocks sharing the activated second sub-word line drivers, according to the mode selection signal.

14. The memory device of claim 13, wherein the paired row address is generated by inverting a most significant bit (MSB) among bits of the row address, the bits designating cell groups.

15. The memory device of claim 13,
wherein the plurality of cell blocks share bit line sense amplifiers with adjacent cell blocks in the column direction, and
wherein cell blocks sharing the first sub-word line drivers do not share the bit line sense amplifiers with cell blocks sharing the second sub-word line drivers.

16. The memory device of claim 13, wherein the adjacent cell blocks in the row direction comprise:
first to m-th normal cell blocks sequentially arranged in the row direction, where m is an integer greater than 1;
at least one ECC cell block; and
(m+1)-th to 2m-th normal cell blocks sequentially arranged in the row direction.

17. The memory device of claim 16, wherein the path control circuit is configured to:
control parity data to be output from the ECC cell block among cell blocks sharing the first sub-word line drivers.

18. The memory device of claim 13, further comprising:
a mode setting circuit configured to generate the mode selection signal based on stored setting data, in response to a mode setting command.

19. The memory device of claim 13, wherein the path control circuit is configured to:
control data to be input/output from the cell blocks sharing the activated first sub-word line drivers, when the mode selection signal is at a first logic level; and
control data to be input/output from the odd-numbered cell blocks sharing the activated first sub-word line drivers and the even-numbered cell blocks sharing the activated second sub-word line drivers, when the mode selection signal is at a second logic level.

20. The memory device of claim 13, wherein the path control circuit comprises:
a sequence selection circuit configured to generate the paired row address, a cell group selection signal, and first and second order control signals based on the row address and the mode selection signal; and
a path setting circuit configured to control input/output of data according to the cell group selection signal and the first and second order control signals.

21. The memory device of claim 20, wherein the sequence selection circuit comprises:
a bit inverter configured to generate the paired row address by inverting a specific bit of the row address;
a control signal generator configured to activate both the first and second order control signals when the mode selection signal is at a first logic level, and activate one of the first and second order control signals based on the specific bit of the row address when the mode selection signal is at a second logic level; and
a row decoder configured to generate the cell group selection signal by decoding the row address when the mode selection signal is at the first logic level, and by decoding the row address and the paired row address when the mode selection signal is at the second logic level.

22. The memory device of claim 20, wherein the path setting circuit comprises:
a first path controller configured to generate lower bits of a first local sensing control signal based on lower bits of the cell group selection signal, a preliminary local sensing control signal, and the second order control signal, and to generate upper bits of the first local sensing control signal based on upper bits of the cell group selection signal, the preliminary local sensing control signal, and the first order control signal; and
a second path controller configured to generate lower bits of a second local sensing control signal based on the lower bits of the cell group selection signal, the preliminary local sensing control signal, and the first order control signal, and to generate upper bits of the second local sensing control signal based on the upper bits of the cell group selection signal, the preliminary local sensing control signal, and the second order control signal.

23. The memory device of claim 22, further comprising:
first local sense amplifiers activated based on respective bits of the first local sensing control signal, and configured to sense and amplify data between the odd-numbered cell blocks and data pads; and
second local sense amplifiers activated based on respective bits of the second local sensing control signal, and configured to sense and amplify data between the even-numbered cell blocks and the data pads.

24. A memory device, comprising:
a plurality of banks each including a plurality of cell blocks arranged in an array in a row direction and a column direction and alternately sharing sub-word line drivers with adjacent cell blocks in the row direction, and configured to activate first sub-word line drivers corresponding to a row address and activate second sub-word line drivers corresponding to a paired row address according to a mode selection signal, during an access operation; and
a path control circuit configured to control data to be input/output from odd-numbered cell blocks among cell blocks sharing the activated first sub-word line drivers and even-numbered cell blocks among cell blocks sharing the activated second sub-word line drivers, according to the mode selection signal.

25. The memory device of claim 24, further comprising:
a bank setting circuit configured to generate the mode selection signal based on a bank address designating one of the plurality of banks.

26. A memory system, comprising:
at least one memory device; and
a memory controller configured to provide a command and an address to the memory device and to transmit and receive data to and from the memory device,
wherein the memory device includes:
a plurality of cell blocks arranged in an array in a row direction and a column direction and divided into cell groups that share a plurality of sub-word lines in the row direction; and
a control circuit configured to, during an access operation, activate a first sub-word line arranged in a first cell group and a second sub-word line arranged in a second cell group, and control data to be input/output from odd-numbered cell blocks in the first cell group and even-numbered cell blocks in the second cell group, or from even-numbered cell blocks in the first cell group and odd-numbered cell blocks in the second cell group.
